(19) United States
(12) Patent Application Publication
(10) Pub. No.: US 2015/0187608 A1
(43) Pub. Date: Jul. 2, 2015

(54) DIE PACKAGE ARCHITECTURE WITH EMBEDDED DIE AND SIMPLIFIED REDISTRIBUTION LAYER

(71) Applicants: Sanka GANESAN, Chandler, AZ (US); Thorsten MEYER, Regensburg (DE); Robert L. SANKMAN, Phoenix, AZ (US); Mark T. BOHR, Aloha, OR (US); Frank ZUDOCK, Regensburg (DE)

(72) Inventors: Sanka GANESAN, Chandler, AZ (US); Thorsten MEYER, Regensburg (DE); Robert L. SANKMAN, Phoenix, AZ (US); Mark T. BOHR, Aloha, OR (US); Frank ZUDOCK, Regensburg (DE)

(21) Appl. No.: 14/141,343

(22) Filed: Dec. 26, 2013

(51) Int. Cl. H01L 21/56; H01L 23/00

(52) U.S. Cl. CPC H01L 21/568; H01L 24/09; H01L 24/17; H01L 24/03; H01L 24/11; H01L 2224/02371; H01L 2224/17104; H01L 2224/033

(57) ABSTRACT

A die package architecture with an embedded die and simplified redistribution layer is described. In one example a method includes attaching a front side of a die to a temporary carrier panel applying a molding compound around the die and over the temporary carrier panel. Removing the temporary carrier, applying a metal routing layer over the front side of the die and the molding compound, and applying a connection array to the metal routing layer.

### FIELD

The present description relates to packaging semiconductor or micromechanical dies and, in particular to packing dies using a mold compound and metal redistribution layer.

### BACKGROUND

Semiconductor and micromechanical dies or chips are frequently packaged for protection against an external environment. The package provides physical protection, stability, external connections, and in some cases, cooling to the die inside the packages. In one type of package, the back and sides of the dies are covered in a mold compound. A redistribution layer is formed over the connection of the front side of the dies. The redistribution layer serves as a package substrate. Connections are then formed on this redistribution layer to allow the package to be connected to a printed circuit board or to be used in some other way.

There is a trend to add more functions to each die. There is also a trend to put more than one chip in a single package. Current packaging technologies include stacking dies on top of each other and placing the dies side-by-side on a single package substrate. Consolidating more functions into a single die and placing more dies into a single package are ways to reduce the size of the electronics and micromechanic systems.

A modern package will use dies that include copper bumps on the front side of the die for external connections. The redistribution layer that is formed over the front side of the die uses at least three layers. The first layer is a dielectric layer, the second layer is the redistribution layer (RDL) and the third layer is a solder resist layer.

The dielectric layer improves RF (Radio Frequency) performance, and absorbs mechanical stress from temperature changes and other sources. The redistribution layer redistributes the small front side copper bumps into larger solder balls. The solder stop layer provides a landing area for the solder balls.

### BRIEF DESCRIPTION OF THE DRAWING FIGURES

Embodiments of the invention are illustrated by way of example, and not by way of limitation, in the figures of the accompanying drawings in which like reference numerals refer to similar elements.

FIG. 1 is a cross-sectional partial view of an example of a copper bump of a silicon die suitable for use with the present invention.

FIG. 2 is a cross-sectional partial view of an example of a bump-less connection for a silicon die suitable for use with the present invention.

FIG. 3 is a cross-sectional partial view of an example of an alternative bump-less connection of a silicon die suitable for use with the present invention.

FIG. 4 is a cross-sectional partial view of an example of another alternative bump-less connection of a silicon die suitable for use with the present invention.

FIG. 5A is a cross-sectional side view diagram of an example of a package using a die with bump-less connections according to an embodiment of the invention.

FIG. 5B is a cross-sectional side view diagram of an example of an alternative package using a die with bump-less connections according to an embodiment of the invention.

FIG. 6A is a cross-sectional side view diagram of an example of a package with a two-level redistribution layer using a die with bump-less connections according to an embodiment of the invention.

FIG. 6B is a cross-sectional side view diagram of an example of a package with a two-level redistribution layer using stacked dies with bump-less connections according to an embodiment of the invention.

FIGS. 7A to 7N are cross-sectional side view diagrams to show stages of an example process of forming a package such as the package of FIG. 5B according to an embodiment of the invention.

FIGS. 8A to 8N are cross-sectional side view diagrams to show stages of an alternative example process of forming a package according to an embodiment of the invention.

FIGS. 9A to 9E are cross-sectional side view diagrams to show stages of another alternative example process of forming a package according to an embodiment of the invention.

FIG. 10 is a block diagram of a computing device incorporating an embedded die package according to an embodiment.

### DETAILED DESCRIPTION

As described herein an integrated circuit die with an ultra-fine pitch aluminum or copper bump-less pads may be mounted into a package on which copper lines are directly plated. This package and fabrication process eliminates the need for Via-0 and the first layer lamination. As a result, the package may have more input/output ports per mm for the die at a lower package cost. The same package technique may be used for a multi-chip package. Two or more dies may also be connected with ultra-fine pitch lines between the bump-less pads on the die. With inexpensive ultra-fine pitch connections, devices may be disaggregated into smaller separate dies. The resulting smaller simpler dies may be produced at lower cost and then combined to produce a system in a package rather than a system in a chip. As an example, a single die may have a system die, a Si voltage regulator die, an analog die and a memory die. These may also be stacked (3D) to achieve higher integration as described herein.

In some embodiments, ultra-fine pitch copper bump-less pads are created on an integrated circuit die. A dielectric epoxy mold compound layer is around the die. Copper lines are then plated directly over the pads of the integrated circuit die and the epoxy mold compound. This creates a co-planar bump-less die dielectric package architecture.

Several variations to the bump-less die architecture are described herein. In one example, there is no bump but the metal layer of the die to which the bump is normally attached. An opening allows electrical connections to the metal layer. In another example, the metal layer is also absent and the connection is to a higher metal layer. The particular selection of metal and dielectric layers may be adapted to suit different die warpage, package embedding, die fabrication process and final product form factor needs.

Any desired bump-less die may be used with the package design and packaging processes described herein. By eliminating the first dielectric lamination and V0 process a higher number of Input/Output ports per mm is obtained. In some embodiments, epoxy dielectric encapsulates the back of the die. In other embodiments the die back side may be exposed.

As described herein, a bump-less die is embedded with die pads facing down not up. An epoxy mold process is used first to embed the die and create a nominally flat bump-less die and epoxy mold surface. Circuit lines are plated directly on this surface without first creating V0. This allows for a simple thin package that can include 3D integration and horizontal die interconnections.

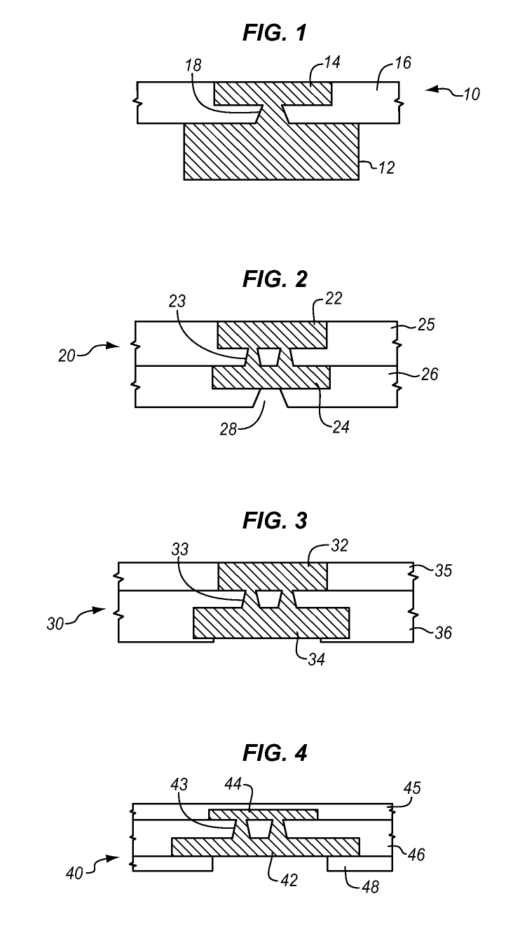

FIG. 1 is a cross-sectional partial view of an example of a copper bump 12 of a silicon die 10. The die has a patterned metal layer TM1 (Thick Metal layer 1) 14 over the internal components and circuitry (not shown) to provide external connections. The first metal layer is covered with an epoxy dielectric layer 16. A via 18 through the epoxy dielectric layer allows a connection to the copper bump 12. The copper bump allows connection to external components such as a package substrate or redistribution layer.

FIG. 2 is a cross-sectional partial view of a bump-less variation of the example of FIG. 1. A die 20 has an M9 (9^{th} Metal) metal layer 22 for routing and interconnection of the internal components. This layer is covered in a low k dielectric layer 25. Vias 23 are formed in the low k layer, filled with copper and connected to the TM1 routing layer 24. As in the example of FIG. 1, the TM1 layer is covered in an epoxy dielectric layer 26 and openings 28 are formed to connect pads of the TM1 to external components. Unlike the example of FIG. 1, there are no copper bumps 12 attached to the TM1 layer through the openings. As a result the thickness, weight, and additional processing steps of the vias and bumps are avoided.

FIG. 3 is a cross-sectional partial view of a bump-less variation of the example of FIG. 2 with still less processing and thickness. The die 30 has the M9 metal layer 32 in low k dielectric 35 and coupled through vias 33 to TM1 34, but instead of the epoxy dielectric layer 26 a thinner dielectric layer 36, such as silicon nitride is applied over the M9. The connection is made directly to the TM1, but with the thinner dielectric 36, there is no need to form a connection opening 28.

FIG. 4 is a cross-sectional partial view of a bump-less variation of the example of FIG. 3 with still less processing and thickness. In this case connections are made directly to the M9 layer 42. The TM1 layer and any associated processing are also avoided. In this view, a metal routing layer 43 above the M9 is shown. This is the M8 (8^{th} metal layer) layer. This layer is formed in a low k dielectric 45. The M8 is then covered in a silicon dioxide or other insulator. Vias 44 are formed through the silicon dioxide. The M9 metal layer 42 and any associated routing is then formed over the M8 layer 43 and connected with the vias. Instead of the TM1 24 of FIGS. 2 and 3, connections are made directly to the M9 layer 42 through the via opening in an outer silicon nitride layer 48.

Typically, the I/O (Input/Output) density for copper bump connections is limited to around 30 IOs (Inputs and Outputs) per mm due to the size of the landing pad on the die for the V0 layer and the copper bump. By eliminating the first dielectric lamination and the V0 layer a higher connection pitch of 35-50 I/O per mm is possible. In this case the connection pad sizes may be from about 20 μm to 45 μm or less depending on the pad-line alignment.

The bump-less configurations shown herein are provided only as examples. Aspects of the illustrated designs may be combined and modified depending on the implementation and the connection to the package. The selection of a bump-less die architecture may also be determined based on cost, die warpage, compatibility with package embedding processes, and product design needs, among other factors.

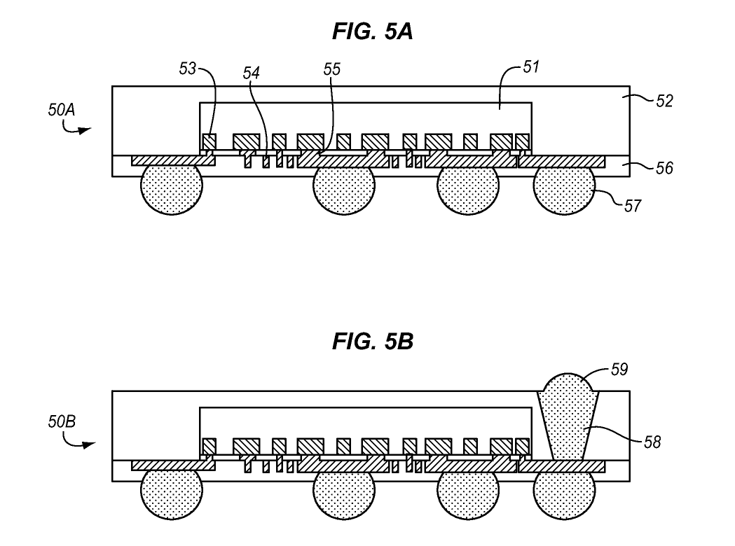

FIG. 5A is a cross-sectional side view diagram of an example of a package using a die with bump-less connections as shown in the examples of FIGS. 2, 3, and 4. The package 50A has a die 51 encapsulated in mold compound 52. The mold compound may be referred to as an overmold as it is molded over and covers at least part of the sides of the die. The active side of the die has an exposed M9 layer 53 as shown, for example, in FIGS. 3 and 4. A silicon nitride layer 54 is applied over the M9 metal contact layer and metal interconnection and routing layers 55 are formed over the silicon nitride with vias down to connect with the M9 layer. A final solder resist layer 56, similar to the epoxy dielectric layer 26 of FIG. 2 is patterned over the interconnection metal layer 55.

The solder resist layer allows a solder ball array 57 to be attached to the bottom of the package. The solder balls may be attached to a circuit board of any of a variety of different types, depending on the particular implementation. As shown in FIG. 5A, the direct connection to the M9 layer and the use of a molded package allow for a thin and compact integrated circuit die package.

FIG. 5B is a cross-sectional diagram of a variation of the package of FIG. 5A. The package 50B is the same as that of FIG. 5A except for the addition of a contact on the top side of the package in addition to those on the bottom side. A through mold via (TMV) 58 is bored, etched, or drilled through the top of the mold compound of the overmold. The TMV extends down to the interconnection and routing layer 55 to make a connection with a pad or land that has been provided for just that purpose. The TMV is filled with a conductive material and a POP (Package on Package) solder ball 59 is placed on the top of the TMV to allow the package to connect to another package to be placed on the top of the TMV. Alternatively, pre-fabricated via bars, embedded in the mold compound may be used in this and other embodiments for such a connection instated of a drilled and filled via. While only four solder balls are shown and only one POP solder ball, in an actual system there may be many more. The diagrams herein are simplified in order to simplify understanding of the principles described herein.

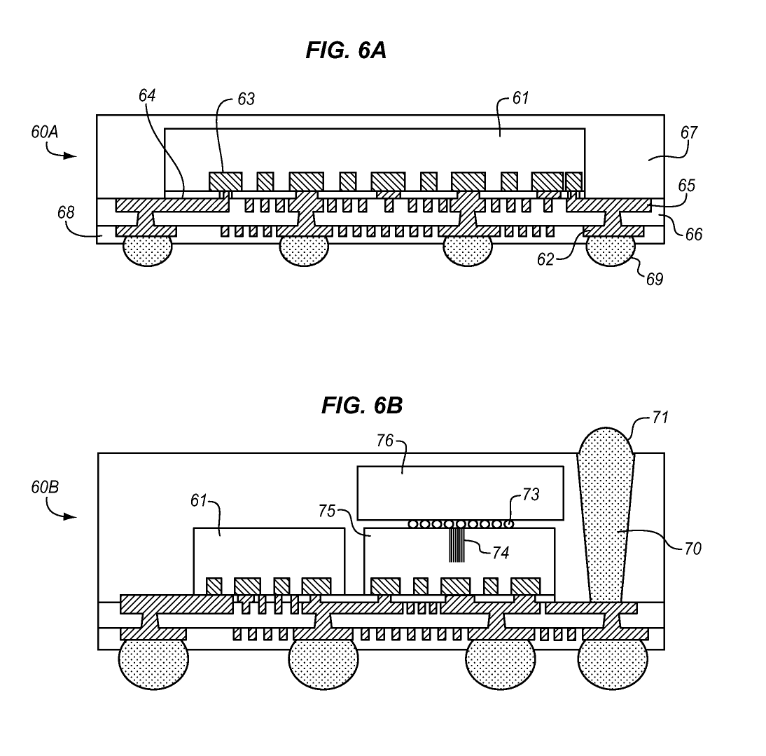

FIG. 6A is a cross sectional side view diagram of an example of a package with two interconnection and routing layers separated by an epoxy dielectric. A die 61 is covered in mold compound 62 and its M9 metal layer 63 is exposed through one end of the overmold for electrical connections. A silicon nitride (e.g. Si₃N₄) layer 64 is applied over the M9 layer and vias are formed through the silicon nitride to connect to first metal routing and interconnection layer 65. Another dielectric layer, such as an epoxy dielectric layer 66 is applied over the first metal routing layer and another metal routing and interconnection layer 67 is formed over the epoxy dielectric. In this way additional routing layers may be formed in order to make any desired connections to an outer solder ball array, a top solder ball array or to other components of the package. The routing layer may also include other components such as passives, depending on the particular implementation.

The bottom of the package is finished with a solder resist pattern 68 for the patterned application of solder. Solder balls 69 are then attached over the gaps in the solder resist pattern for attachment to an external circuit board, package on package connections or for any other purpose.

FIG. 6B is a cross-sectional side view diagram of a package fabricated with all of the same components as the package of FIG. 6A. The die 61 is encapsulated or covered in a mold compound 62 and two layers of metal routing and interconnection patterns 65, 67 are applied to the bottom of the die and the overmold. The metal layers are separated by one or more dielectric layers 64, 66.

The package of FIG. 6B is expanded to include a TMV (Through-Mold Via) 70 connected between the metal routing layers 65, 67 at the bottom of the package and a solder ball 71 or other type of electrical connector at the top of the package. As in the example of FIG. 5B, the through-mold via may be used to connect the die to a second package to be connected on the top of the illustrated package or the through mold via may be used to connect the die to the second package. Alternatively, the through mold via may be used to attach wire line connectors to the connector at the top of the package. These connections may be used for power, data, to connect passive devices or for any other purpose.

The package may also include additional dies. A second die 75 is placed horizontally beside the first die 61. The metal routing layers may be formed over the second die and the mold compound in the same way that they are formed over the first die. They may also be used to connect the two dies, depending on the purpose of the package and the dies. A third die 76 is stacked over the second die within the package. The dies may first be stacked, covered in mold compound then the routing layers may be formed. However, the package may be assembled in other ways depending on the particular implementation.

In the illustrated example, the second die has TSV's (Through-Silicon Vias) 73 from the circuitry on the front side of the die through to the back side of the die. A set of lands or pads are formed on the back side of the die to connect to the TSV's. The third die 76 has a front side connection array of pads, lands or bumps 74 to align with the lands for the TSV's and connect to the second die. This type of die stacking is provided as an example, the dies may be stacked in any of a variety of different ways. The package of FIG. 6B is able to accommodate dies of different types to perform different functions in a single package. This may be for purposes of a SIP (System in a Package) or to provide an integrated functional package that relies on different technologies. Such a package may be an optical, radio, sensor, or other type of package. For a processor package, the first die may be a power supply and analog interface die. The second die may be a processor, and the third die may be a memory. Any of a variety of other combinations is possible.

The package configurations shown in FIGS. 5A, 5B, 6A, and 6B are provided as examples. Different features of different packages may be combined to form any of a variety of different variations in the number of dies and their configurations. In addition more or fewer metal routing layers may be used. While only one TMV is shown, there may be many more depending on the needs for a particular packet architecture. While the connections are shown as being made to the M9 metal layer of the die, the metal routing layers may be made to connect in any of the ways shown in FIGS. 2, 3, and 4. While M8, M9 and TM1 are used as layer designations, a different designation system may be used. In addition, for some dies, there may not be an M8 or M9 layer. Similar types of connections may be made to other layers that are near the exposed face of the die. This layer may be M3 or M4, for example or any other layer depending on the nature of the die and the connections that are to be made.

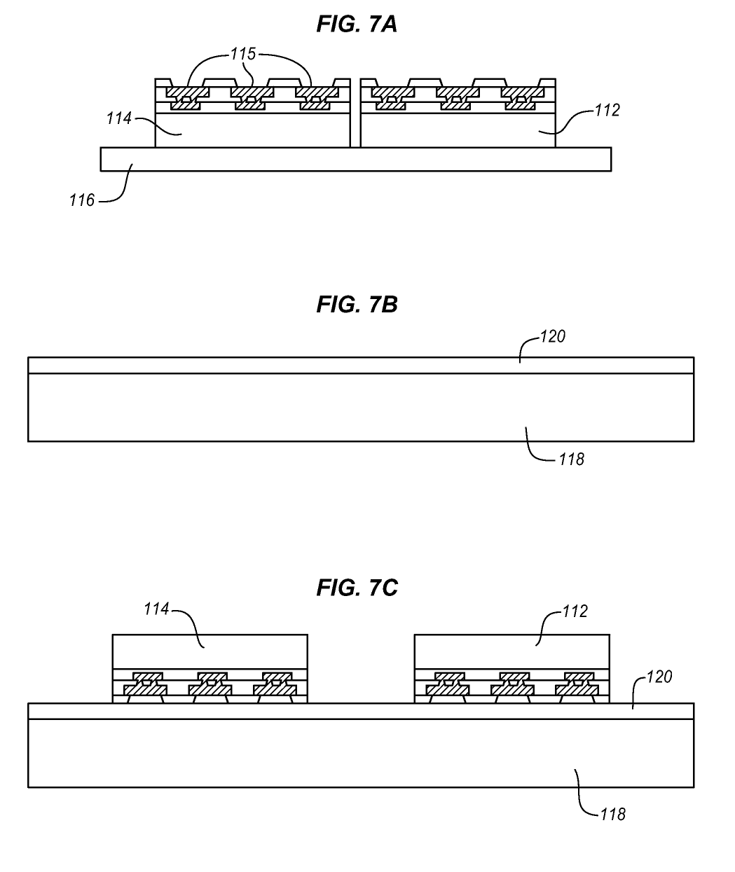

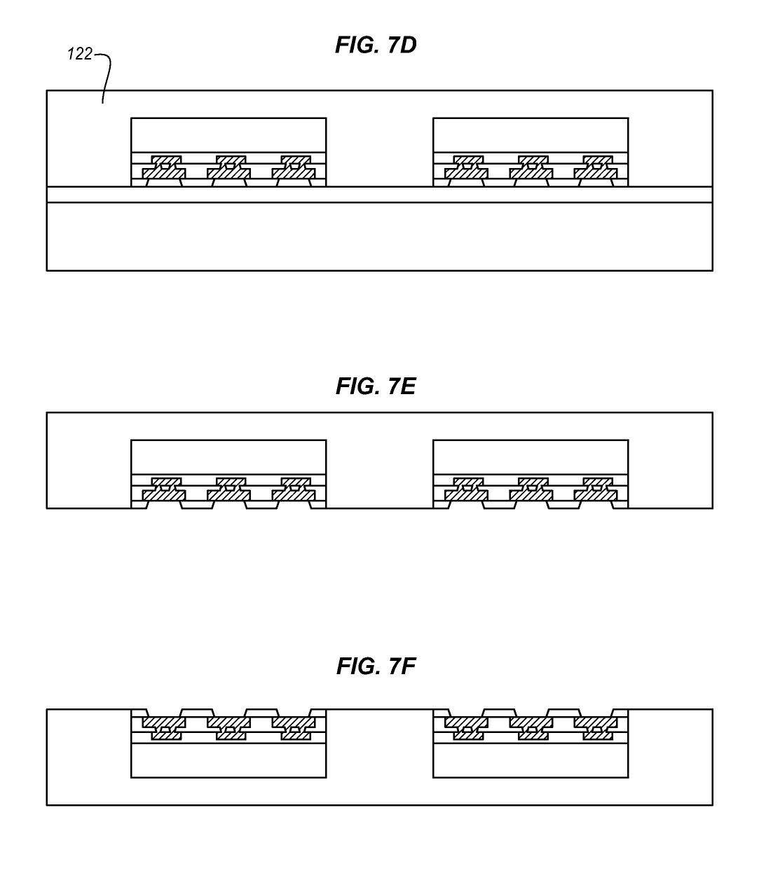

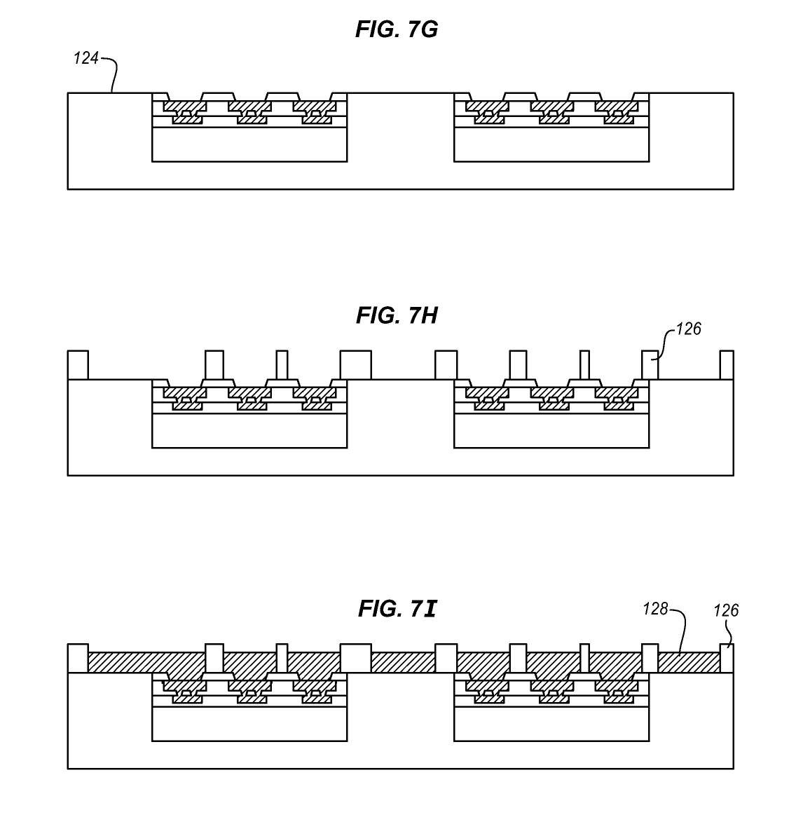

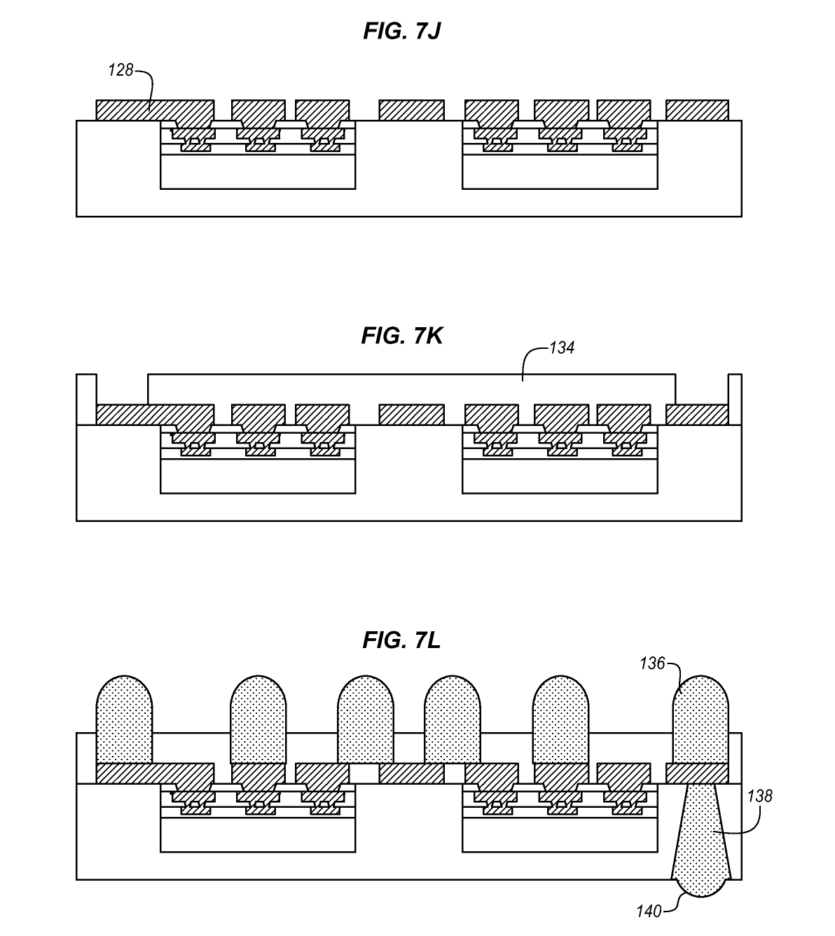

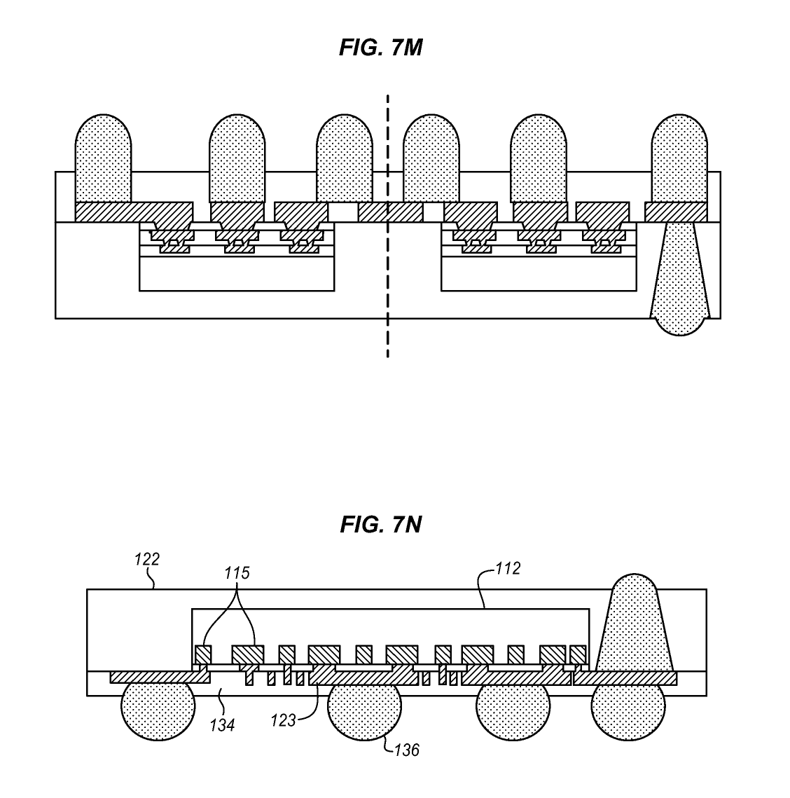

FIGS. 7A to 7N are cross-sectional side view diagrams to show stages of an example process of forming a package such as the package of FIG. 5B. This process may be modified to produce any of the other package described herein and variations thereof. FIG. 7A shows a carrier wafer 116 upon which two dies 112, 114 have been formed. Each die has a back side silicon substrate attached to the carrier wafer and front side circuitry and interconnection layers shown as facing upward in this example. The dies may be prepared for example with bump-less connection arrays 115 as shown in more detail in FIGS. 2, 3, and 4 or some variation of such a bump-less connection. The dies are diced and separated from the carrier wafer 116.

In FIG. 7B a temporary panel carrier of silicon, glass, ceramic, metal alloy, or another material is laminated with an adhesive. Any one of a variety of different adhesives may be used. The selected adhesive is designed to hold the placed dies as in FIG. 7C and then release them as in FIG. 7E by applying some physical, thermal, or chemical energy to the adhesive. In one example, the adhesive is double sided tape, however soluble or heat release adhesive may be used instead. In FIG. 7C, the dies are attached to the adhesive of the temporary carrier. A pick and place machine may be used, for example to place the front sides of the dies onto the carrier.

In FIG. 7D, the dies are overmolded. Any of a variety of different molding compounds may be used including an epoxy dielectric, depending on the intended use of the package. The molding compound may cover the back side of the dies as shown or expose the back side for other processes or structures including heat spreaders and other connectors. With the molding compound 122 applied, the adhesive 120 may be released and the temporary carrier 118 removed as shown in FIG. 7E. This exposes the front side connections of the two dies. The assembly can be flipped over to allow access to the front sides of the dies as shown in FIG. 7F. The front side connections may be treated and cleaned with e.g. plasma etching and the mold compound surface may be activated to improve the adhesion of the metal layers to the mold compound. The plasma etching may be combined with Ar, O₂, He, SiOH or another element or compound to enhance its effectiveness. With the dies prepared the metal routing and interconnection layers may be applied.

In FIG. 7G a seed metal 124, such as Ti, Ti—Cu, or another seed metal may applied over the entire top surface to enhance the adhesion of the coming metal layers. In some embodiments, there may be open silicon edges on the dies. The open edges may be caused by the dicing process in the kerf or the dicer or it may be caused by other front side processes. In order to prevent the seed layer from shorting out the edges, a partial coating may be added over the exposed edges. The partial coating may be deposited only in the chip area in the dicing kerf, or in all areas that are not otherwise covered. In some embodiments a hard passivation (e. g. SiN, SiO) layer (not shown) may be applied to the front side of the die. The coating may extend up to and abut or overlap the hard passivation layer. In some embodiments, the passivation layer may extend over and into the dicing kerf. In FIG. 7H, the top surface is patterned. This may be done using a DFR (Dry Film Resist) 126 which may be deposited, exposed and developed or in any other desired way. In FIG. 7I copper 128 or another metal is deposited over the DFR to obtain the desired pattern for the first metal layer. The metal plating step may then be finished with a thin tin or other coating to enhance adhesion to the underlying metal with subsequent dielectric layers.

In FIG. 7J, the DFR and any remaining seed layer are stripped. The front side of the die may be cleaned using any a variety of acid or etch treatments. This leaves the intended metal routing and interconnection layer 128. In FIG. 7K a dielectric layer such as a solder mask 134 is applied over the metal layer to isolate the metal and define a pattern for a solder connection array. In FIG. 7L, the solder connections are put in place using the solder mask pattern. Solder balls 136 are attached to the areas that are not covered in the patterned solder mask. Through mold vias 138 may also be performed through the back side of the package. These may be topped with solder balls 140 for POP, wire lead, or another type of connection.

In FIG. 7M, the packages may be singulated to form separate individual packages using a saw, laser, or other cutting device. This provides the final package of FIG. 7N which has an embedded die 112 with a bump-less connection array 115 and external connections 136 to the top and the bottom. This package is similar to that to FIG. 5B described herein. The process may be modified by not forming any TMVs in FIG. 7L to provide a package such as that of FIG. 5A. In addition, stacked dies may be used instead of single dies to arrive at a package similar to that of FIG. 6B. More or fewer steps or layers may be added or subtracted, depending on the particular implementation.

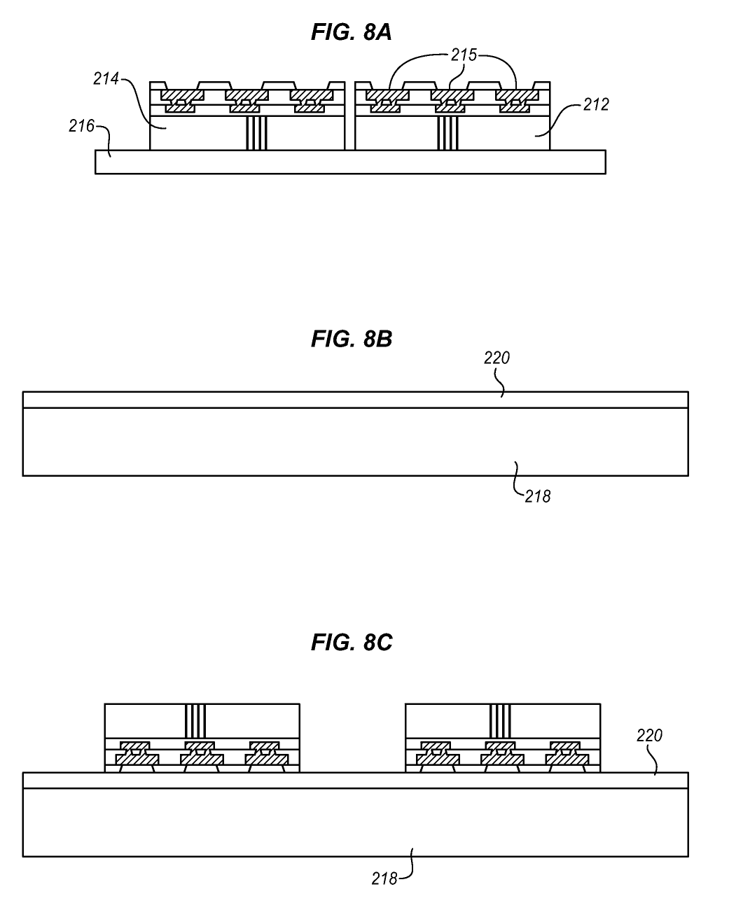

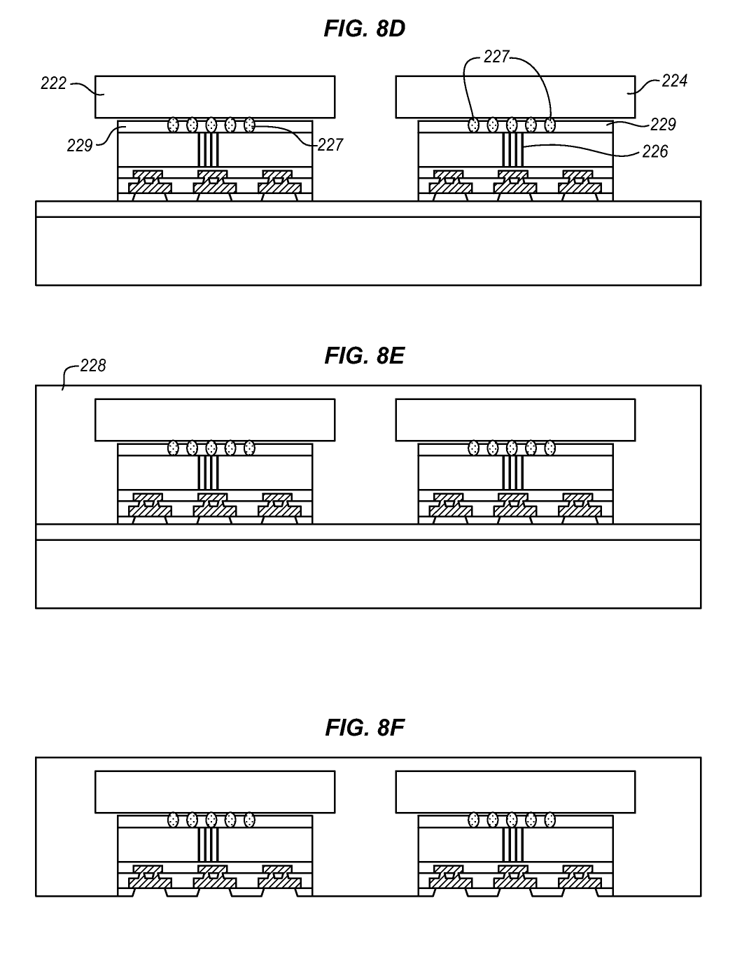

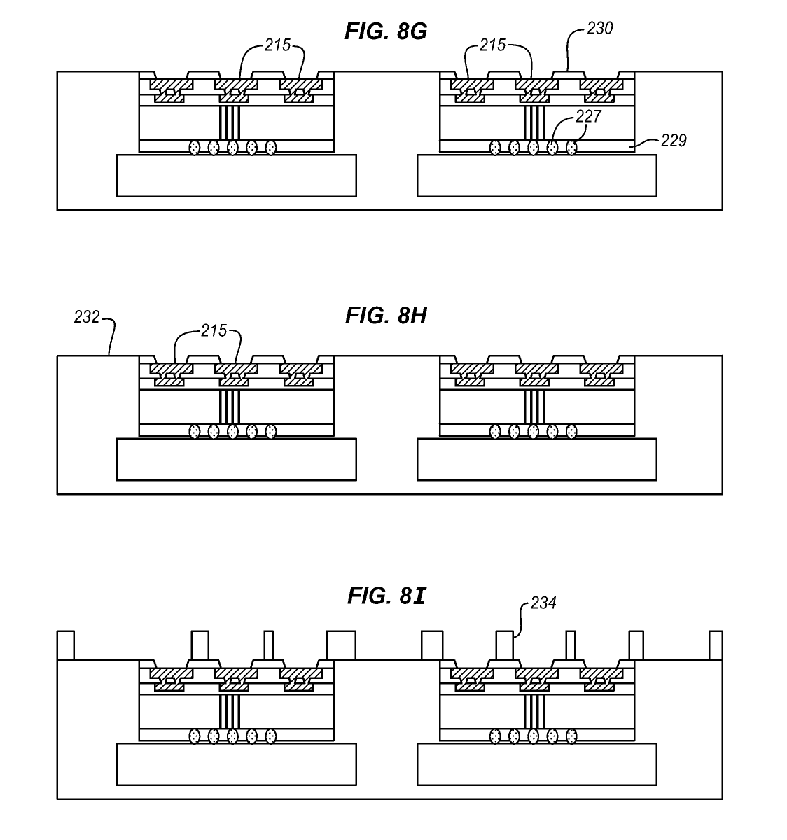

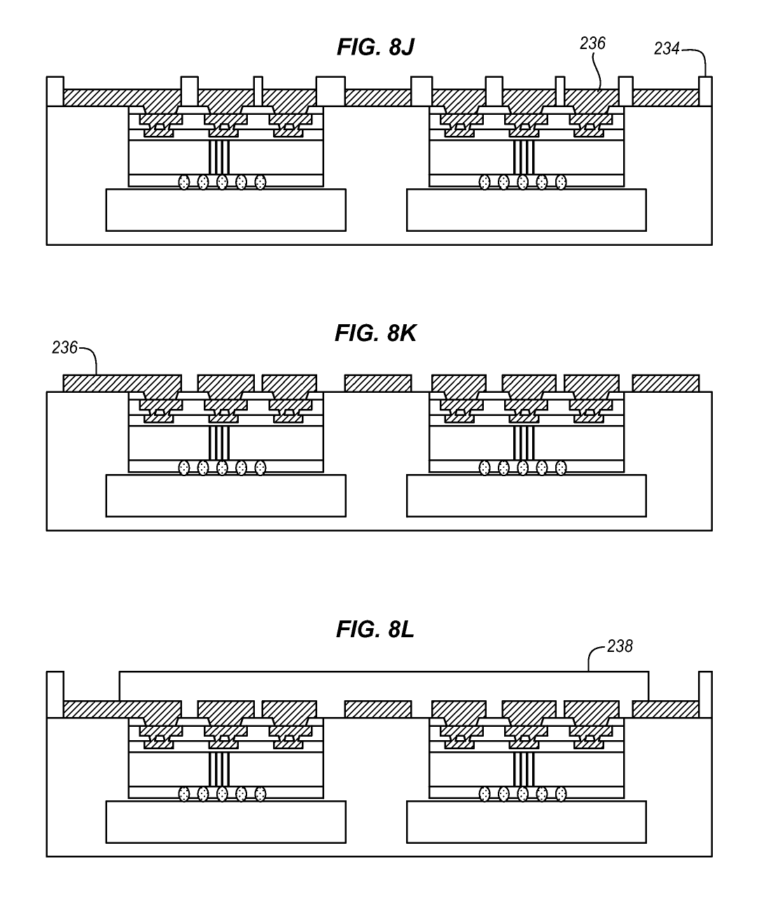

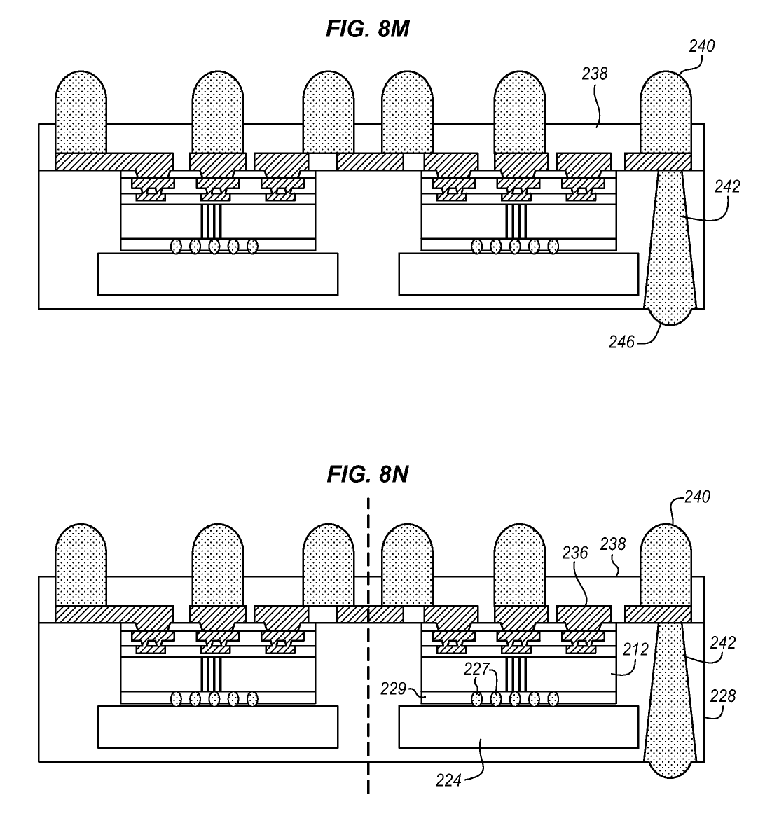

FIGS. 8A to 8N are side cross-sectional views of forming packages using an alternative process flow. In this example bump-less dies are stacked and then embedded in a mold compound. Referring to FIG. 8A, dies 212, 214 are formed form a silicon substrate that is carried on a carrier wafer. The dies have front side bump-less connection arrays 215 as described herein or formed in any other way. The dies are diced and released from the carrier wafer and then supplied to, for example, a pick and place machine. In FIG. 8B a temporary panel carrier 218 is cleaned and a releasable adhesive 220 is applied. In this example, the adhesive is laminated to only one side of the carrier. While only two dies are shown herein, typically many more dies are formed on the same silicon substrate 216. Only two dies are shown in order to simplify the drawing figures. In addition, the temporary panel carrier 218 may be made much larger than shown so that it may simultaneously carry many more than two dies.

In FIG. 8C, the dies are attached to the carrier 218 using the pick and place machine. The front sides of the dies with the bump-less connection array are attached with the adhesive and the back sides of the dies are exposed. This allows for stacking in FIG. 8D. Additional dies 222, 224 may optionally be stacked over the first two dies 212, 214 while the back sides of the first two dies are exposed. In the illustrated example, TSVs 226 were formed on the dies before they were diced. Attachment areas of the TSVs usually come with metal (Cu/Ni/Au, Cu/Co/W/Au) pads. In some embodiments solder (Sn) may be coated on the Cu metal pads or lands. These pads or lands may then be cleaned after the dies are placed in the temporary carrier to enable a robust connection with the dies 222, 224. The additional dies may then be attached using an appropriate process.

In the illustrated example, the additional dies have solder balls 227. A solder epoxy underfill 229 is applied over the exposed back side of the dies. The additional dies are then placed over the first two dies and held in place by the underfill. The temporary carrier with the stacked dies is then attached using e.g. thermo-compression bonding, to melt the solder and provide an electrical connection as well as to cure the epoxy underfill. The die stacks are then ready to be embedded and packaged. Additional processes may also be applied to the dies while attached to the temporary carrier. This may include applying treatments to the exposed back side of the dies. Forming additional structures, such as TSV's, routing layers, attachment arrays, and cooling or heat spreading devices. The temporary panel carrier may be made of a material that can sustain higher temperatures and more harsh chemical environments than mold compound. As a result, some processes may be performed on the carrier before the mold compound is applied. In addition, additional connections may be made between the stacked dies or between the dies and other components. For example, passives may be attached to the back side of either of the stacked dies.

In FIG. 8E a mold compound 228 is applied over the temporary carrier covering the die stacks. With the mold compound in place, the dies are fixed in position relative to each other. In FIG. 8F, the temporary panel carrier 218 is removed by releasing the adhesive or by physical force. In FIG. 8G the molded dies may be flipped over to provide access to the front side connections. The die surface and exposed mold surface may be cleaned, treated, and prepared for the next operations.

In FIG. 8H the assembly is prepared for the application of metal routing layers, isolation layers, and connection arrays. A seed metal is deposited over the bump-less connection array 215 to promote adhesion. In FIG. 8I, a DFR 234 is applied, exposed, and developed. In FIG. 8J, copper 236 is electroplated over the DFR pattern and finished with a tin plating. In FIG. 8K, the DFR may be stripped, the seed layer may be stripped and the connection layers may be cleaned. This leaves the metal routing layer 236 with its tin coating electrically connected to the connection array. Additional metal routing layers may be formed in a similar way using alternating layers of dielectric and patterned metal with connecting vias. In the example of FIGS. 6A and 6B, there are two metal layers, however, more may be used, depending on the particular implementation and desired end device.

In FIG. 8L the die is prepared for external connections. A solder mask 238 is defined and applied over the metal routing layer 236. The solder mask isolates the metal and defines where solder will be placed. In FIG. 8M, solder balls 240 are formed in the openings of the solder mask pattern. Additional connections may also be formed, such as TMV's 242 with connection lands or pads 246 for other external connections. Finally, the packages may be singulated as shown in FIG. 8N. Additional finishing operations may also be applied to the package depending on the particular implementation.

The operations shown in FIGS. 7A to 7N and 8A to 8M may also be used to form a multiple die package with horizontal combinations. Dies may be placed side-by-side as shown in FIGS. 7C and 8C and the routing layers of FIGS. 7J and 8K may be formed to connect the two dies to each other or only to external connectors depending on the nature of the dies. Finally when the packages are singulated as in FIGS. 7M and 8N, they may be singulated to include multiple dies in a single package. Multiple die architectures may be formed using horizontal or vertical combinations and combinations of horizontal and vertical combination for 3D integration. This allows for multiple function packages, system packages and other types of devices.

As shown in both process flow examples, the bump-less die is embedded with the die pads covered with a temporary carrier and facing down as opposed to the die bump being exposed and facing up. In addition, the epoxy mold is applied early in the process to create a surface with the die over which circuit lines are directly plated. The mold is applied over the temporary carrier so that the die and the mold are at about the same level, or are co-planar. This relatively flat surface allows the circuit lines to be applied without any intermediate layers and processing steps. The surface lines may be created without first creating a V0 layer.

In the description above, the front side of the die is attached directly to the adhesive layer on the temporary carrier. When the overmold is applied, the molding compound is applied along the sides of the die to meet the temporary carrier wherein the die is attached to the temporary carrier. The metal layers that are applied over the die and the mold compound are more robust when the mold compound is level with or co-planar with the die.

In embedded wafer packages, a passivation layer, such as a polyimide layer, may first be applied to the front side of the die before the die is attached to the temporary carrier wafer. After the molding compound is applied to the die and after the temporary carrier is removed, a dielectric layer, then redistribution layer (RDL) and then a solder resist layer are applied over the front side of the die. The first dielectric layer, applied in the backend manufacturing process, covers the top side of the silicon die and the mold compound area. This includes the edge of the active Si die area and also the side wall of the silicon chip, exposed when the mold compound is not co-planar with the die. This layer improves RF (Radio Frequency) performance and buffers mechanical stresses from thermal cycling.

The dielectric layer is deposited onto the die and molding by spin-coating, lamination or any other technique. If there is uncovered silicon in the dicing kerf that may cause shorts, then a front end-applied dielectric may be used to cover the uncovered silicon. This may also be done if the layers are laminated. After a soft bake, the photosensitive material in the dielectric is exposed to light with a lithography stepper. Then the material is developed and finally cured. Alternatively, a laser may be used to drill the vias into the dielectric.

Photosensitive dielectric materials are expensive. Material is wasted by the spin-coating process. The fabrication equipment for spin-coating and for photolithography is also very expensive and the photolithography process requires many separate operations.

As described above, a two layer set-up may be used for some types of die connection arrays. The first layer is the metal redistribution layer and the second layer is the solder resist layer. The dielectric layer may be skipped. In addition, the process of applying a copper connection bump array to the front side of the die can also be skipped. One important function of the dielectric layer is to isolate the exposed silicon on the sides and front side of the die. If these are directly covered by a metal layer there may be short circuits from the Cu-RDL lines to the silicon. In addition, after a die is diced from a wafer, the die has a seal ring and a crack stop. These may also cause be short circuited when directly connected to a metal layer.

To prevent the metal redistribution layer from electrically connecting with exposed silicon, a variety of different electrical insulators may be applied to the die. To be effective, the insulator must be applied after the wafer is diced. Each silicon die typically has a dielectric layer, a front-end polyimide layer, that is applied over the whole wafer before it is diced. However, when dicing the wafer, the saw will expose the edge of the die and the remaining part of the dicing kerf. The dicing kerf is normally wider than the dicing width. After dicing the edge of the die is not covered with a passivation layer like the center of the front end face of the die is. These areas at the corner of the die are vulnerable to causing short circuits when covered by the Cu-RDL.

One technique for protecting this corner is to add an additional dielectric layer. This additional layer may be applied after dicing and before placing the die on the temporary carrier wafer. The addition layer may be applied to the exterior surface of the die adding a deposition, spin-coating, or dipping operation to the process. The coating may be a polyimide or any of a variety of other durable isolating materials that can electrical insulate the die from a metal layer, such as copper. For vapor deposition, the layer may need to be structured after it is deposited.

A second technique is to place the die on the temporary carrier wafer so that when the mold compound is applied it will completely cover the outer edge of the die. If the die is placed directly onto a typical adhesive, even including a double sided tape, then the adhesive is moderately resilient. The die sinks into the adhesive. As a result, during the molding process of e.g. eWLB wafers, the dies are pressed slightly deeper into the mold foil than the mold compound can fill. In other words, the mold cannot reach around the dies due to the adhesive being in the way. This leads to a die stand-off, the die stands off the mold compound surface by approximately 5 μm. This die stand-off and the accessible surface part of the silicon not protected by a front-end polyimide layer cause a short as described above. The short circuit is between a redistribution passing the interface between the die and the mold compound, shorting the RDL to the sidewall of the die.

In order to allow the mold compound to reach around the top edge of the die, an additional layer may be applied over the front side of the die before the die is placed on the adhesive. If this layer is sufficiently thick, then it will sink into the adhesive but the die will be supported above the adhesive. This will allow the mold compound to cover the top edge of the die. The additional layer may be a dielectric layer that passivates the area and provides isolation. Such a layer provides for the build-up of a direct connection of passivation and mold compound on the top of the Si die. Such a layer may be applied and structured on the front end of the die at the silicon wafer level before the wafer is diced and the die is placed on the temporary carrier.

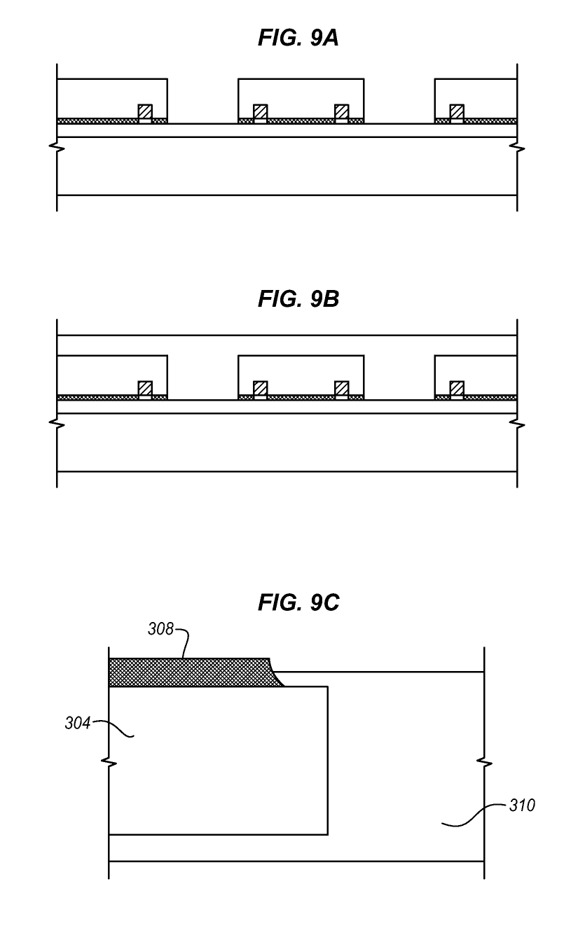

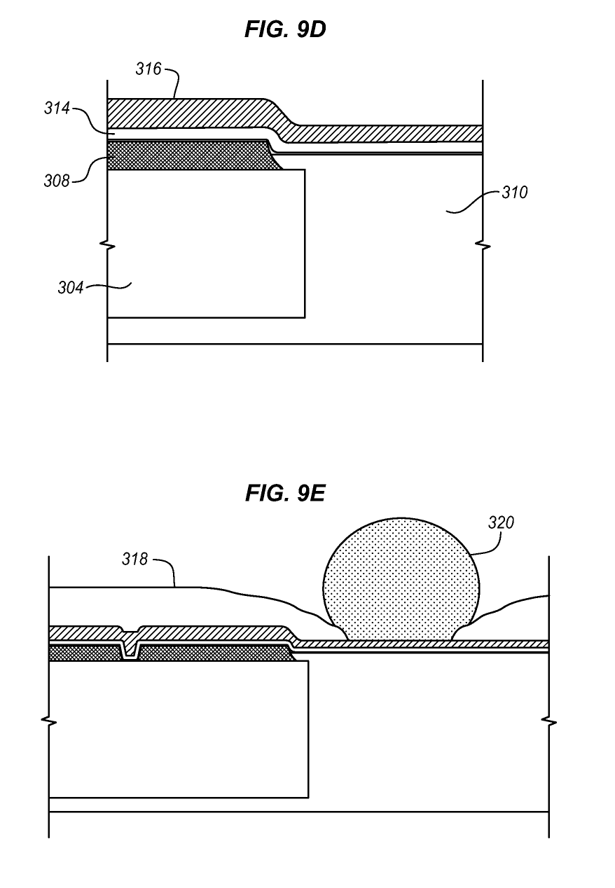

FIGS. 9A to 9E are cross-sectional side view diagrams to show stages of an example process for forming a package. FIG. 9A shows an example of a temporary carrier wafer 301 with an adhesive layer 302, such as a double-sided tape. Dies 304 are placed on the adhesive by a pick and place machine so that they are held in place. The dies have various connection features 306, such as the bump-less pads described above, and a passivation layer 308 over the pads.

In FIG. 9B, a mold compound 310 is applied over the dies and in FIG. 9C, the temporary carrier is removed and the exposed top surfaces of the dies is cleaned and prepared for the application of a metal redistribution layer. Due to the passivation layer that has been formed over the top of the dies, the mold compound covers the outer edge of the top of the die over to the edge of the passivation layer. The mold compound also covers the sides of the dies all the way to the top.

There are different ways to build-up a direct connection from mold compound and passivation. The wafers may be used directly from a front end process that includes the application of a passivation layer. In some cases, wafers may be covered with passivation and polyimide in the front end process. These layers may be used to create a stand-off between the top of the die and the adhesive layer.

Alternatively, a thick dielectric, or other thick polymer or isolation layer, is applied to the silicon wafer. The thickness must be enough to allow part of the layer to sink into the adhesive and still allow the mold compound to penetrate between the top of the die and the adhesive layer on the edges of the die. This may be the matrix of the mold compound with only small or even no filler materials. The thickness of the dielectric may also be selected depending on the filler size used in the mold compound. Since such a polyimide layer is thick, there will be a gap between the mold tape and the silicon top side at the edge of the die. This gap is at the edge of the die where no polyimide layer is applied. If the polyimide layer is thick enough, then the gap allows the mold compound to flow into it, making contact with the polyimide layer on the die in this gap. Even if the mold compound does not contact or abut the polyimide layer it may be sufficient if it covers the exposed areas of the die that are semi-conductive and may cause shorts against the metal layer.

In this way, the mold compound coats the accessible silicon and possibly the original die side of the die standoff, if the die has a standoff. The mold compound 310 may also be in physical contact with the passivation or dielectric layer 308. If not in contact with the passivation layer, then the mold compound may be used to at least cover the conductive parts of the silicon. At the same time, the mold compound embeds the die on more than 5 faces, the four sides, the back, and a part of the top. As mentioned above, the back may be exposed for additional connections, depending on the particular implementation.

The results may be enhanced, especially with thinner passivation, polyimide, or epoxy dielectric layer layers by reducing the force of the pick & place process to press the dies less deeply into the adhesive. In addition, the adhesive may be made less resilient or thinner. The isolating layer 308 may also be expanded to cover a larger area of the die including the seal ring and crack stop

Referring to FIG. 9D, after the temporary carrier is removed and the dies are flipped as in FIG. 9C, then a seed layer 314 and metal redistribution layer (RDL) 316 are applied directly over the passivation layer 308 and mold compound 310. This layer provides connection to the pads, bumps, lands, or other connections 306 on the top side of the die.

As shown in FIG. 9D, all of the silicon of the die 304, except the exposed connection pads within the polyimide layer, are either coated with the polyimide layer 308 or embedded with the mold compound 310. This avoids a need for an additional dielectric layer over the die because there is no exposed silicon that could be shorted by a redistribution layer 314.

FIG. 9E shows a solder mask 318 is applied over the RDL and a solder ball grid array 320 or other type of connection or land array is applied over the RDL. As described above, the RDL and solder ball grid may include connections to back side connectors, to other dies within the package or for a variety of other purposes in addition to providing connections to the die.

By applying the RDL directly over the top side of the die, the cost of the dielectric layer material, the application process and the application equipment are avoided. The techniques described herein allow a direct connection of the polyimide, isolation, or passivation layer and the mold compound to be made on the top of the die. In some examples, either polyimide or mold compound covers the seal ring and crack stop. The resulting eWLB package has no dielectric layer applied on the reconstituted safer under the redistribution layer. Such an approach is particularly suited for small packages or small die packages or for packages with solder balls only or mainly positioned over the mold compound area, however, the invention is not so limited.

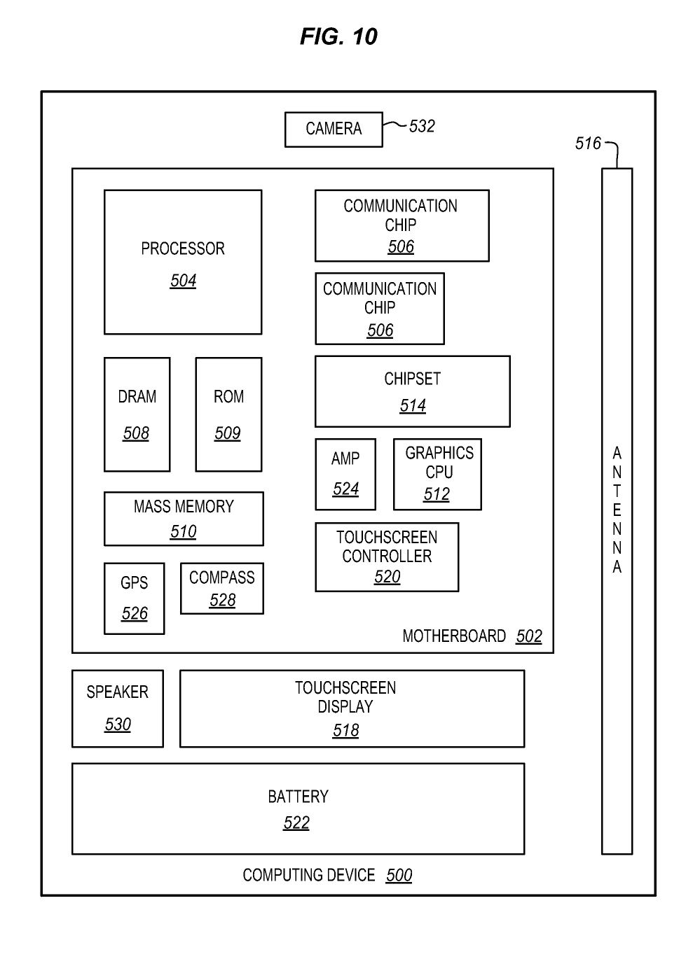

FIG. 10 illustrates a computing device 500 in accordance with one implementation of the invention. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

Depending on its applications, computing device 500 may include other components that may or may not be physically and electrically coupled to the board 502. These other components include, but are not limited to, volatile memory (e.g., DRAM) 508, non-volatile memory (e.g., ROM) 509, flash memory (not shown), a graphics processor 512, a digital signal processor (not shown), a crypto processor (not shown), a chipset 514, an antenna 516, a display 518 such as a touchscreen display, a touchscreen controller 520, a battery 522, an audio codec (not shown), a video codec (not shown), a power amplifier 524, a global positioning system (GPS) device 526, a compass 528, an accelerometer (not shown), a gyroscope (not shown), a speaker 530, a camera 532, and a mass storage device (such as hard disk drive) 510, compact disk (CD) (not shown), digital versatile disk (DVD) (not shown), and so forth). These components may be connected to the system board 502, mounted to the system board, or combined with any of the other components.

The communication chip 506 enables wireless and/or wired communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

In some implementations, any one or more of the components of FIG. 5, such as the integrated circuit die of the processor, memory devices, communication devices, or other components may be bump-less dies or packaged with molding compound and a redistribution layer, as described herein. The term “processor” may refer to any device or portion of a device that processes electronic data from registers and/or memory to transform that electronic data into other electronic data that may be stored in registers and/or memory.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

Embodiments may be implemented as a part of one or more memory chips, controllers, CPUs (Central Processing Unit), microchips or integrated circuits interconnected using a motherboard, an application specific integrated circuit (ASIC), and/or a field programmable gate array (FPGA).

References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

In the following description and claims, the terms “chip” and “die” are used interchangeably to refer to any type of microelectronic, micromechanical, analog, or hybrid small device that is suitable for packaging and use in a computing device.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

The following examples pertain to further embodiments. The various features of the different embodiments may be variously combined with some features included and others excluded to suit a variety of different applications. Some embodiments pertain to a method that includes attaching a front side of a die to a temporary carrier panel. applying a molding compound around the die and over the temporary carrier panel. removing the temporary carrier, applying a metal routing layer over the front side of the die and the molding compound, and applying a connection array to the metal routing layer.

In further embodiments applying the molding compound comprises applying the molding compound over the die. In further embodiments, applying a metal routing layer comprises applying the metal routing layer over a bump-less connection array of the die.

In further embodiments, the bump-less connection array comprises a plurality of lands over an M9 metal layer of the die. In further embodiments, applying a connection array comprises applying a solder ball grid array.

In further embodiments, applying a solder ball grid array comprises depositing a patterned solder resist directly over the metal layer to expose a portion of the metal layer and depositing solder over exposed portion of the metal layer.

Further embodiments include attaching a second die to a back side of the die after attaching the die to the temporary carrier and before applying a molding compound. Further embodiments include applying a dielectric layer over at least a portion of the top side of the die before attaching the front side to the temporary carrier.

In further embodiments the dielectric layer is a passivation layer. In further embodiments the temporary carrier includes an adhesive layer to hold the die on the temporary carrier and wherein the dielectric layer is thicker than the adhesive layer.

In further embodiments applying a metal routing layer comprises applying a metal routing layer over the dielectric layer. In further embodiments the dielectric layer has a peripheral edge on the front side of the die and wherein applying a molding compound comprises applying a molding compound between the temporary carrier and the front side of the die to the peripheral edge of the dielectric layer. In further embodiments the mold compound is a dielectric.

Some embodiments pertain to an integrated circuit package with a die having a bump-less connection array, a metal routing layer coupled on a first side to the bump-less connection array, a solder ball array coupled to a second side of the metal routing layer opposite the first side, and an overmold surrounding the die and extending to the first side of the metal routing layer.

In further embodiments, a surface of the overmold is substantially level with the front side of the die. In further embodiments, the bump-less connection array is on a front side of the die and the overmold covers a back side of the die opposite the front side of the die. In further embodiments, the bump-less connection array is an M9 layer.

Further embodiments include a second metal routing layer between the solder ball array and the first metal routing layer. Further embodiments include a through-mold via between the first metal routing layer and a position on the outside of the overmold. Further embodiments include a passivation layer over the bump-less connection array and between the bump-less connection array and the metal routing layer.

In further embodiments, the passivation layer is at least 5 μm thick.

Some embodiments pertain to a computing device having a plurality of packaged integrated circuit dies, a user interface, and a display, at least on integrated circuit die being in a package. The integrated circuit die package has a die having a bump-less connection array, a metal routing layer coupled on a first side to the bump-less connection array, a solder ball array coupled to a second side of the metal routing layer opposite the first side, and an overmold surrounding the die and extending to the first side of the metal routing layer.

Further embodiments include a second metal routing layer between the solder ball array and the first metal routing layer. Further embodiments include a passivation layer over the bump-less connection array and between the bump-less connection array and the metal routing layer. In further embodiments, the passivation layer is at least 5 μm thick.

1. A method comprising:
attaching a front side of a die to a temporary carrier panel;
applying a molding compound around the die and over the temporary carrier panel;
removing the temporary carrier;
applying a metal routing layer over the front side of the die and the molding compound; and
applying a connection array to the metal routing layer.

2. The method of claim 1, wherein applying the molding compound comprises applying the molding compound over the die.

3. The method of claim 1, wherein applying a metal routing layer comprises applying the metal routing layer over a bump-less connection array of the die.

4. The method of claim 1, wherein the hump-less connection array comprises a plurality of lands over an M9 metal layer of the die.

5. The method of claim 1, wherein applying a connection array comprises applying a solder ball grid array.

6. The method of claim 1, wherein applying a solder ball grid array comprises depositing a patterned solder resist directly over the metal layer to expose a portion of the metal layer and depositing solder over exposed portion of the metal layer.

7. The method of claim 1, further comprising attaching a second die to a back side of the die after attaching the die to the temporary carrier and before applying a molding compound.

8. The method of claim 1, further comprising applying a dielectric layer over at least a portion of the top side of the die before attaching the front side to the temporary carrier.

9. The method of claim 8, wherein the dielectric layer is a passivation layer.

10. The method of claim 8, wherein the temporary curler includes an adhesive layer to hold the die on the temporary carrier and wherein the dielectric layer is thicker than the adhesive layer.

11. The method of claim 8, wherein applying a metal routing layer comprises applying a metal routing layer over the dielectric layer.

12. The method of claim 8, wherein the dielectric layer has a peripheral edge on the front side of the die and wherein applying a molding compound comprises applying a molding compound between the temporary carrier and the front side of the die to the peripheral edge of the dielectric layer.

13. The method of claim 8, wherein the mold compound is a dielectric.

14.-25. (canceled)
